(19) United States
(12) Patent Application Publication
(10) Pub. No.: US 2025/0298107 A1
(43) Pub. Date: Sep. 25, 2025

(54) MAGNETIC RESONANCE IMAGING APPARATUS

(71) Applicant: CANON MEDICAL SYSTEMS CORPORATION, Otawara-shi (JP)

(72) Inventors: Ryo EGUCHI, Ako (JP); Hajime TANABE, Okayama (JP); Dai YAMASHIRO, Himeji (JP)

(73) Assignee: CANON MEDICAL SYSTEMS CORPORATION, Otawara-shi (JP)

(21) Appl. No.: 19/081,253

(22) Filed: Mar. 17, 2025

(30) Foreign Application Priority Data
Mar. 19, 2024 (JP) 2024-043727

(51) Int. Cl. G01R 33/3815; G01R 33/38

(52) U.S. Cl. CPC G01R 33/3815; G01R 33/3804

(57) ABSTRACT

A magnetic resonance imaging apparatus according to an exemplary embodiment includes a superconducting coil, a first container, a radiation shield, a second container, first to third pipes, and a switching assembly. The first container houses the superconducting coil which is immersed in refrigerant liquid, and also contains refrigerant gas generated by vaporization of the refrigerant liquid. The radiation shield houses the first container. The second container houses the radiation shield. The first pipe directs the refrigerant gas in the first container into an outside of the radiation shield. The second pipe allows the refrigerant gas from the first pipe, to pass through so as to enable the refrigerant gas to exchange heat with the radiation shield. The third pipe discharges the refrigerant gas from the first pipe, to an outside. The switching assembly directs the refrigerant gas from the first pipe, into the second pipe or the third pipe.

### CROSS-REFERENCE TO RELATED APPLICATIONS

This application is based upon and claims the benefit of priority from Japanese Patent Application No. 2024-043727, filed Mar. 19, 2024, the entire contents of which are incorporated herein by reference.

### FIELD

Exemplary embodiments described herein relate generally to a magnetic resonance imaging apparatus.

### BACKGROUND

A magnetic resonance imaging apparatus includes a superconducting magnet that can generate a magnetic force stronger than a magnetic force generated by a normal electromagnet. The superconducting magnet acts under a very low temperature. Therefore, the superconducting magnet is housed in a refrigerant container filled with refrigerant (e.g., liquid helium).

The refrigerant container is housed in a radiation shield in order to reduce heat intrusion into the refrigerant container. The radiation shield generates heat due to eddy current loss caused by generation of a gradient magnetic field in imaging. When the temperature of the radiation shield rises in imaging, quality of an image obtained by the magnetic resonance imaging apparatus may be degraded. Therefore, it is necessary to maintain the temperature of the radiation shield in imaging within a predetermined temperature range (hereinafter, referred to as being maintained in a steady state). Japanese Patent Application Laid-Open No. H7-74019 proposes a configuration in which a pipe for discharging evaporated refrigerant to the outside is arranged in the radiation shield to maintain the cooling of the radiation shield.

In peripheral equipment including the superconducting magnet, evaporated refrigerant may be temporarily released into the outside air when initial cooling is performed, when liquid injection is performed, when excitation/de-excitation is performed, when quenching occurs, and when a refrigeration machine is stopped (due to transportation, intermittent operation of refrigeration machine, blackout, failure, etc.).

In the peripheral equipment including the superconducting magnet, there are situations where the efficiency of cooling the radiation shield is to be increased, and situations where it is unnecessary to increase the efficiency of cooling the radiation shield. Examples of the situations where the efficiency of cooling the radiation shield is to be increased include where initial cooling is performed, when quenching occurs, and when the refrigeration machine is stopped. On the other hand, examples of the situations where it is unnecessary to increase the efficiency of cooling the radiation shield include when additional liquid injection is performed, and when excitation/de-excitation is performed.

### BRIEF DESCRIPTION OF THE DRAWINGS

FIG. 1 is a block diagram illustrating an entire configuration of a magnetic resonance imaging apparatus according to a first exemplary embodiment;

FIG. 2 is a sectional view illustrating a configuration of a static magnetic field magnet and a periphery thereof according to the first exemplary embodiment;

FIG. 3 is a perspective view illustrating a first arrangement example of a pipe covering a radiation shield according to the first exemplary embodiment;

FIGS. 4A and 4B are perspective views illustrating a second arrangement example of the pipe covering the radiation shield according to the first exemplary embodiment, where FIG. 4A is a diagram illustrating an arrangement example of the pipe on an outer cylinder and end plates of the radiation shield in the second arrangement example, and FIG. 4B is a diagram illustrating an arrangement example of the pipe on an inner cylinder of the radiation shield in the second arrangement example;

FIG. 5 is a sectional view illustrating a configuration of the static magnetic field magnet and a periphery thereof according to the first exemplary embodiment;

FIG. 6 is a sectional view illustrating a configuration of the static magnetic field magnet and a periphery thereof according to a first modification of the first exemplary embodiment;

FIG. 7 is a sectional view illustrating a configuration of the static magnetic field magnet and a periphery thereof according to a second modification of the first exemplary embodiment;

FIG. 8 is a sectional view illustrating a configuration of the static magnetic field magnet and a periphery thereof according to a second exemplary embodiment;

FIG. 9 is a sectional view illustrating a configuration of the static magnetic field magnet and a periphery thereof according to a third exemplary embodiment;

FIG. 10 is a sectional view illustrating a configuration of the static magnetic field magnet and a periphery thereof according to the third exemplary embodiment;

FIG. 11 is a sectional view illustrating a configuration of the static magnetic field magnet and a periphery thereof according to the third exemplary embodiment;

FIG. 12 is a sectional view illustrating a configuration of the static magnetic field magnet and a periphery thereof according to the third exemplary embodiment;

FIG. 13 is a sectional view illustrating a configuration of the static magnetic field magnet and a periphery thereof according to the third exemplary embodiment; and

FIG. 14 is a sectional view illustrating a configuration of the static magnetic field magnet and a periphery thereof according to a fourth exemplary embodiment.

### DETAILED DESCRIPTION

A magnetic resonance imaging apparatus according to an exemplary embodiment includes a superconducting coil, a first container, a radiation shield, a second container, a first pipe, a second pipe, a third pipe, and a switching assembly. The first container houses the superconducting coil which is immersed in refrigerant liquid. The first container also contains refrigerant gas generated by vaporization of the refrigerant liquid. The radiation shield houses the first container. The second container houses the radiation shield.

The first pipe directs the refrigerant gas in the first container into an outside of the radiation shield. The second pipe is connected to the first pipe, and allows the refrigerant gas from the first pipe, to pass through so as to enable the refrigerant gas to exchange heat with the radiation shield. The third pipe is connected to the first pipe, and discharges the refrigerant gas from the first pipe, to an outside. The switching assembly directs the refrigerant gas from the first pipe, into the second pipe or the third pipe.

Various Embodiments will be described hereinafter with reference to the accompanying drawings.

In the following exemplary embodiments, parts denoted by the same reference numerals perform similar operation, and repetitive description is appropriately omitted.

### First Exemplary Embodiment

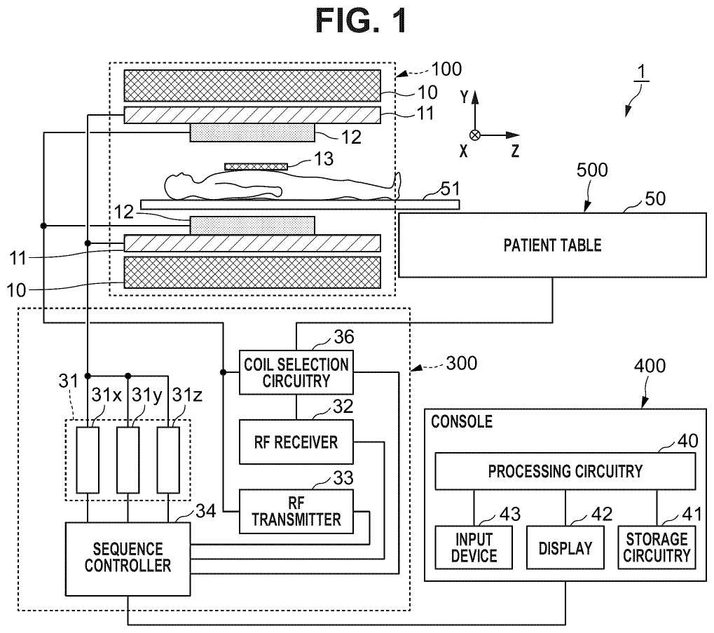

FIG. 1 is a block diagram illustrating an entire configuration of a magnetic resonance imaging apparatus 1 according to a first exemplary embodiment. The magnetic resonance imaging apparatus 1 includes a magnet rack 100, a control cabinet 300, a console 400, a patient table 500, and a radio frequency (RF) coil 13.

The magnet rack 100 includes a static magnetic field magnet 10, a gradient magnetic field coil 11, and a whole body (WB) coil 12. These components are housed in a cylindrical housing.

The control cabinet 300 includes a gradient magnetic field power supply 31 (X-axis power supply 31x, Y-axis power supply 31y, and Z-axis power supply 31z), coil selection circuitry 36, an RF receiver 32, an RF transmitter 33, and a sequence controller 34.

The console 400 includes processing circuitry 40, storage circuitry 41, a display 42, and an input device 43. The console 400 functions as a host calculator. The patient table 500 includes a patient table main body 50 and a top board 51. The static magnetic field magnet 10 of the magnet rack 100 has a substantially cylindrical shape, and generates a static magnetic field in a bore to which a subject, for example, a patient, is conveyed. The bore is a space inside the cylinder of the magnet rack 100. The static magnetic field magnet 10 internally includes superconducting coils 15, and the superconducting coils 15 are cooled to a very low temperature by liquid helium. The static magnetic field magnet 10 generates a static magnetic field by applying a current supplied from a static magnetic field power supply (not illustrated), to the superconducting coils 15 in an excitation mode. Thereafter, when the static magnetic field magnet 10 is shifted to a permanent current mode, the static magnetic field power supply is disconnected from the static magnetic field magnet 10. When the static magnetic field magnet 10 is shifted to the permanent current mode once, the static magnetic field magnet 10 continuously generates a large static magnetic field for a long time, for example, for one year or more.

The gradient magnetic field coil 11 also has a substantially cylindrical shape, and is fixed to an inner side of the static magnetic field magnet 10. The gradient magnetic field coil 11 applies a gradient magnetic field to the subject in directions of an X-axis, a Y-axis, and a Z-axis by currents supplied from the gradient magnetic field power supplies 31x, 31y, and 31z, respectively.

The patient table main body 50 of the patient table 500 can move the top board 51 in the vertical direction and the horizontal direction. The patient table main body 50 of the patient table 500 moves the subject placed on the top board 51 to a predetermined height before imaging. Thereafter, in imaging, the patient table main body 50 of the patient table 500 moves the top board 51 in the horizontal direction, thereby moving the subject into the bore.

The WB coil 12 is also referred to as a whole body coil, and is fixed in a substantially cylindrical shape inside the gradient magnetic field coil 11 so as to surround the subject. The WB coil 12 transmits RF pulses transmitted from the RF transmitter 33, toward the subject. The WB coil 12 receives magnetic resonance (MR) signals emitted from the subject due to excitation of hydrogen nuclei.

As illustrated in FIG. 1, the magnetic resonance imaging apparatus 1 includes the RF coil 13 in addition to the WB coil 12. The RF coil 13 is placed in proximity to a body surface of the subject. The RF coil 13 includes a plurality of element coils. The plurality of element coils is arranged in an array inside the RF coil 13, and is also referred to as a phased array coil (PAC). The RF coil 13 has several types. The RF coil 13 has types of, for example, a body coil disposed in a chest part, an abdomen part, or a leg part of the subject as illustrated in FIG. 1, and a spine coil installed on a back side of the subject.

The RF transmitter 33 generates the RF pulses based on an instruction from the sequence controller 34. The generated RF pulses are transmitted to the WB coil 12 or the RF coil 13, and are applied to the subject. The application of the RF pulses causes the MR signals to be generated from the subject. The MR signals are received by the RF coil 13 or the WB coil 12.

The MR signals received by the RF coil 13, more specifically, the MR signals received by the element coils in the RF coil 13 are transmitted to the coil selection circuitry 36 through cables disposed on the top board 51 and the patient table main body 50. The coil selection circuitry 36 selects signals output from the RF coil 13 or signals output from the WB coil 12, in accordance with a control signal output from the sequence controller 34 or the console 400.

The selected signals are output to the RF receiver 32. The RF receiver 32 analog-to-digital (AD) converts channel signals, specifically, the MR signals, and outputs the converted signals to the sequence controller 34. The MR signals converted into digital signals are also referred to as raw data in some cases. The AD conversion may be performed inside the RF coil 13 or by the coil selection circuitry 36.

The sequence controller 34 individually drives the gradient magnetic field power supply 31, the RF transmitter 33, and the RF receiver 32 to scan the subject under the control of the console 400. In response to receiving raw data from the RF receiver 32 through the scanning, the sequence controller 34 transmits the raw data to the console 400.

The sequence controller 34 includes processing circuitry (not illustrated). The processing circuitry includes hardware components, such as a processor configured to execute a predetermined program, a field programmable gate array (FPGA), and an application specific integrated circuit (ASIC).

The console 400 includes the storage circuitry 41, the input device 43, the display 42, and the processing circuitry 40. The storage circuitry 41 is a storage medium including a read only memory (ROM), a random access memory (RAM), and an external storage device, such as a hard disk drive (HDD) and an optical disk device. The storage circuitry 41 stores various types of information and data, and various programs to be executed by the processor in the processing circuitry 40. The input device 43 is, for example, a mouse, a keyboard, a track ball, and a touch panel, and includes various devices for an operator to input various types of information and data. The display 42 is a display device, such as a liquid crystal display panel, a plasma display panel, and an organic electroluminescence (EL) panel.

The processing circuitry 40 is circuitry including, for example, a CPU and a dedicated or general-purpose processor. The processor realizes various types of functions described below by executing various programs stored in the storage circuitry 41. The processing circuitry 40 may include hardware components, such as an FPGA and an ASIC.

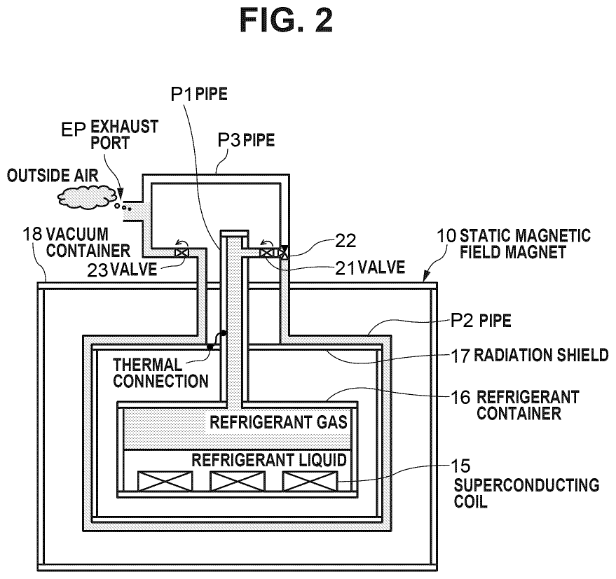

FIG. 2 is a sectional view illustrating a configuration of the static magnetic field magnet 10 and a periphery thereof according to the first exemplary embodiment. The static magnetic field magnet 10 illustrated in FIG. 2 corresponds to an upper part of the static magnetic field magnet 10 of the magnet rack 100 illustrated in FIG. 1. Thus, in FIG. 2, the bore is formed below the static magnetic field magnet 10, and the subject is placed inside the bore. As illustrated in FIG. 2, the static magnetic field magnet 10 includes the superconducting coils 15, a refrigerant container 16, a radiation shield 17, a vacuum container 18, and pipes P1, P2, and P3. The superconducting coils 15 generates a static magnetic field to the subject.

The refrigerant container 16 houses the superconducting coils 15. In the refrigerant container 16, the superconducting coils 15 is immersed in refrigerant liquid (liquid of refrigerant), and refrigerant gas that is generated by vaporization of the refrigerant liquid is contained. The refrigerant liquid is, for example, liquid helium, and cools the superconducting coils 15 to a very low temperature of about 4 kelvin (K). The refrigerant container 16 is an example of a first container.

The radiation shield 17 is maintained at a temperature that is higher than a temperature of the refrigerant liquid but is sufficiently lower than a temperature of outside air, for example, about 30 K to about 80 K, to prevent the intrusion of radiation heat from the outside. Outside air is an example of the outside. As a material of the radiation shield 17, for example, aluminum is used. The vacuum container 18 includes a vacuum internal space, and houses the radiation shield 17. The radiation shield 17 includes a vacuum internal space, and houses the refrigerant container 16. The vacuum container 18 is an example of a second container.

The pipe P1 directs the refrigerant gas in the refrigerant container 16 to the outside of the radiation shield 17. In FIG. 2, the pipe P1 is connected to the outer surface of the outer cylinder of the refrigerant container 16, penetrates through the radiation shield 17, and extends up to the outside of the vacuum container 18. The pipe P1 is thermally connected to the radiation shield 17. The pipe P1 is an example of a first pipe. The pipe P2 is connected to the pipe P1 and allows the refrigerant gas introduced from the pipe P1 to pass through and exchange heat with the radiation shield 17. In FIG. 2, the pipe P2 is branched from the pipe P1, penetrates inward through the vacuum container 18, goes around the radiation shield 17, then penetrates outward through the vacuum container 18, and is connected to an exhaust port EP. In other words, the pipe P2 allows the refrigerant gas introduced from the pipe P1 to pass therethrough while enabling the refrigerant gas to exchange heat with the radiation shield 17, and then discharges the refrigerant gas to the outside. The pipe P2 is an example of a second pipe. In FIG. 2, while the illustration is simplified, there is a pipe (not illustrated) that extends from an MRI imaging room where the magnetic resonance imaging apparatus 1 is installed to the outdoors, serving as a pipe for discharging the refrigerant gas to the outside. This pipe is installed indoors and is connected to the exhaust port EP that opens to the outdoors. The outdoors is an example of the outside. The pipe P2 may be in contact with or out of contact with the radiation shield 17 as long as the pipe P2 enables heat exchange with the radiation shield 17.

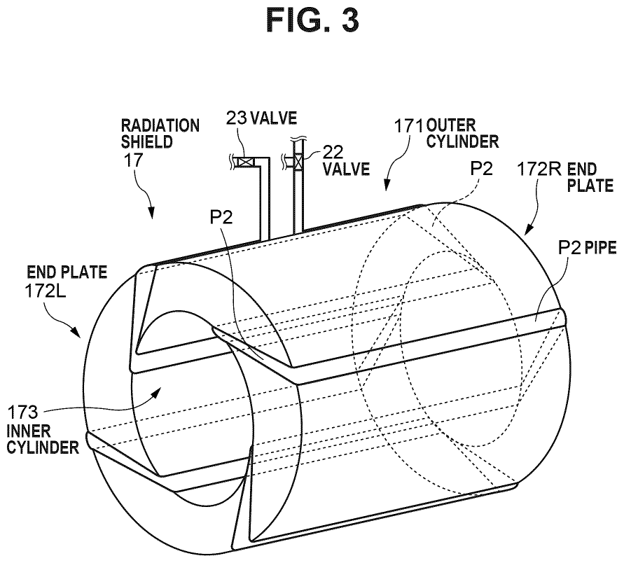

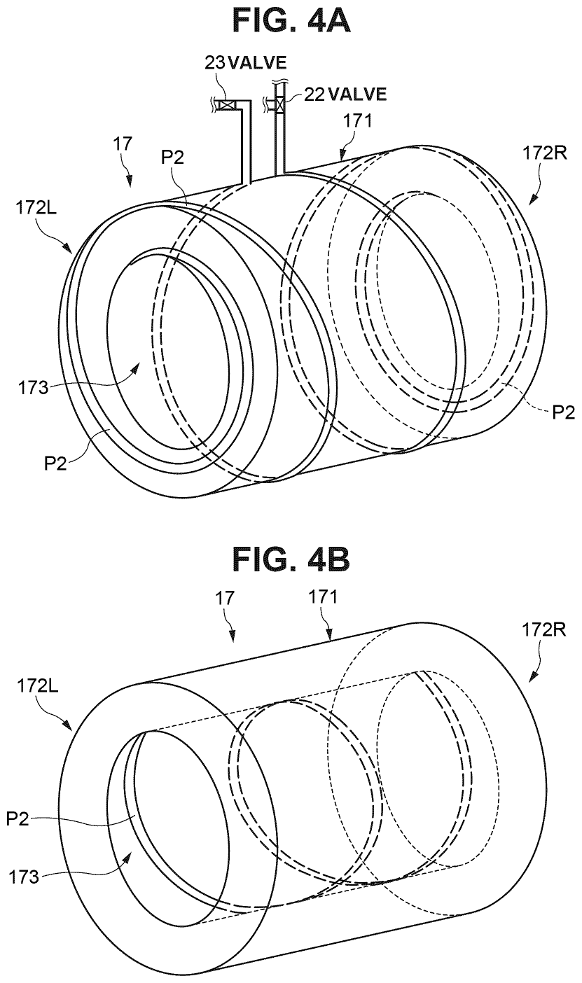

FIG. 3 and FIGS. 4A and 4B are diagrams each illustrating an arrangement example of the pipe P2 going around the radiation shield 17. FIG. 3 is a perspective view illustrating a first arrangement example of the pipe P2 that covers the radiation shield 17 according to the first exemplary embodiment. The radiation shield 17 is installed inside the static magnetic field magnet 10, and has a cylindrical shape. An outer surface of the radiation shield 17 is covered with the pipe P2.

The radiation shield 17 includes an outer cylinder 171, end plates 172R and 172L, and an inner cylinder 173. The outer cylinder 171 serves as the outside surface of the radiation shield 17. The end plates 172R and 172L serve as both side surfaces of the radiation shield 17, and are each formed in a doughnut shape. The end plate 172R is an end plate on a right side. The end plate 172L is an end plate on a left side. The inner cylinder 173 serves as an inside surface of the radiation shield 17. For convenience of description, when the radiation shield 17 illustrated in FIG. 3 is viewed obliquely from the front left, a top of the end plate 172L is referred to as a 0-degree position, and positions in a clockwise direction are referred to as a 45-degree position, a 90-degree position, and the like in order.

As illustrated in FIG. 3, the pipe P2 is arranged at a 0-degree position, a 90-degree position, a 180-degree position, and a 270-degree position on the outer cylinder 171 of the radiation shield 17. In contrast, the pipe P2 is arranged at a 45-degree position, a 135-degree position, a 225-degree position, and a 315-degree position on the inner cylinder 173 of the radiation shield 17. Eight lines of the pipe P2 that connect parts of the pipe P2 of the outer cylinder 171 and parts of the pipe P2 of the inner cylinder 173 to one another are arranged in the end plates 172L and 172R of the radiation shield 17.

For example, the pipe P2 that connects a part of the pipe P2 arranged at the 0-degree position on the outer cylinder 171 and a part of the pipe P2 arranged at the 45-degree position on the inner cylinder 173 to each other is arranged on the end plate 172R. The pipe P2 that connects a part of the pipe P2 arranged at the 45-degree position on the inner cylinder 173 and a part of the pipe P2 arranged at the 90-degree position on the outer cylinder 171 to each other is arranged on the end plate 172L. In such a manner, the parts of the pipe P2 arranged on the outer cylinder 171 and the parts of the pipe P2 arranged on the inner cylinder 173 are connected.

FIGS. 4A and 4B are perspective views illustrating a second arrangement example of the pipe P2 that covers the radiation shield 17 according to the first exemplary embodiment. FIG. 4A illustrates an arrangement example of the pipe P2 on the outer cylinder 171, the end plate 172R, and the end plate 172L of the radiation shield 17 in the second arrangement example. FIG. 4B illustrates an arrangement example of the pipe P2 on the inner cylinder 173 of the radiation shield 17 in the second arrangement example. For convenience of description, FIG. 4A and FIG. 4B are separate, but in practice, the configurations in FIGS. 4A and 4B are integrated. In other words, the configuration illustrated in FIG. 4A and the configuration illustrated in FIG. 4B can be used in combination.

As illustrated in FIG. 4A, the pipe P2 is arranged in a helical manner on the outer cylinder 171 of the radiation shield 17. The pipe P2 is arranged in two loops on the outer cylinder 171, extending from the 0-degree position on the end plate 172L to the 0-degree position on the end plate 172R. As illustrated in FIG. 4B, the pipe P2 is arranged in a helical manner on the inner cylinder 173 of the radiation shield 17. The pipe P2 is arranged in two loops, extending from the 0-degree position on the end plate 172L to the 0-degree position on the end plate 172R of the inner cylinder 173.

As illustrated in FIG. 4A, the pipe P2 is arranged in a spiral shape manner on the end plate 172R. The pipe P2 arranged in the spiral manner connects the part of the pipe P2 arranged at the 0-degree position on the outer cylinder 171 and the part of the pipe P2 arranged at the 0-degree position on the inner cylinder 173. The pipe P2 is arranged on the end plate 172L in a spiral manner. The pipe P2 in the spiral manner arranged connects the part of the pipe P2 arranged at the 0-degree position on the outer cylinder 171 and the part of the pipe P2 arranged at the 0-degree position on the inner cylinder 173. In such a manner, the part of the pipe P2 arranged on the outer cylinder 171 and the part of the pipe P2 arranged on the inner cylinder 173 are connected. A valve 22 and a valve 23 illustrated in FIG. 2 are disposed at both ends of the pipe P2 arranged on the outer cylinder 171. The above-described first and second arrangement examples of the pipe P2 are examples for description, and the arrangement is not limited thereto.

Referring back to FIG. 2, the pipe P3 is connected to the pipe P1, and directly discharges refrigerant gas introduced from the pipe P1 to outdoors. In FIG. 2, the pipe P3 is branched from the pipe P1, passes through the outside of the static magnetic field magnet 10, and is then connected to the exhaust port EP. The pipe P3 is an example of a third pipe.

The valves 21, 22, and 23 introduce the refrigerant gas introduced from the pipe P1 to the pipe P2 or the pipe P3 in conjunction with one another. The valves 21, 22, and 23 are examples of a switching assembly.

The valve 21 is disposed in the pipe P1 near a portion to which the pipe P2 is connected, and is opened/closed based on pressure of the refrigerant gas in the pipe P1. When the pressure of the refrigerant gas in the pipe P1 exceeds a predetermined threshold, the valve 21 allows the refrigerant gas to pass from the inside to the outside of the pipe P1. The valve 21 prevents the refrigerant gas from reversely flowing from the outside into the inside of the pipe P1. For the valve 21, a check valve that opens or closes at predetermined operation pressure is used, for example.

The valve 22 directs the refrigerant gas introduced from the pipe P1, to the pipe P2 or the pipe P3. In other words, the valve 22 forms a path from the pipe P1 to the pipe P2, or a path from the pipe P1 to the pipe P3. For the valve 22, a switching valve such as a three-direction valve is used, for example.

The valve 23 is arranged in the pipe P2 between the static magnetic field magnet 10 (vacuum container 18) and the exhaust port EP, and opens or closes based on pressure of the refrigerant gas in the pipe P2. When the pressure of the refrigerant gas in the pipe P2 exceeds a predetermined threshold, the valve 23 allows the refrigerant gas to pass from the pipe P2 to the exhaust port EP side. The valve 23 prevents the refrigerant gas from reversely flowing from the exhaust port

EP side of the pipe P2 into the pipe P2. For the valve 23, a check valve is used, for example.

The valves 21 and 23 may be valves (ball valve, globe valve, etc.) that manually are manually opened and closed.

In FIG. 2, the valve 21 opens the path, the valve 22 forms the path from the pipe P1 to the pipe P2, and the valve 23 opens the path. Accordingly, the refrigerant gas in the refrigerant container 16 passes through the pipes P1 and P2, and is then discharged from the exhaust port EP to the outside. In this case, since the refrigerant gas passes through the pipe P2, the refrigerant gas can exchange heat with the radiation shield 17. In other words, the static magnetic field magnet 10 at least includes the pipes P1, P2, and P3 through which the refrigerant gas capable of exchange heat with the radiation shield 17 flows, and the valve 22 capable of switching the path through which the refrigerant gas flows. When efficiency of heat exchange with the radiation shield 17 is to be increased by using sensible heat of the refrigerant gas (e.g., during initial cooling, quenching, in refrigerator stopped state, or imaging), the path through which the refrigerant gas flows is switched by the valve 22. This makes it possible to increase the efficiency of the heat exchange between the refrigerant gas and the radiation shield 17, thus increasing the efficiency of cooling the radiation shield 17. As a result, the time to be taken to bring the temperature of the radiation shield 17 into a steady state (80 K in present exemplary embodiment) can be reduced.

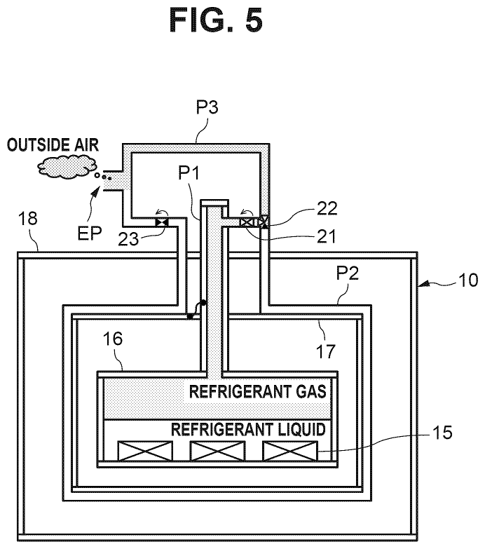

FIG. 5 is a diagram illustrating the configuration of the static magnetic field magnet 10 and a periphery thereof according to the first exemplary embodiment. The configuration illustrated in FIG. 5 is the same as in FIG. 2. As in FIG. 2, the valve 21 opens the path. However, unlike FIG. 2, the valve 22 forms the path from the pipe P1 to the pipe P3, and the valve 23 closes the path. Thus, the refrigerant gas in the refrigerant container 16 passes through the pipes P1 and P3, and is then discharged from the exhaust port EP to the outside air. In this case, the refrigerant gas does not pass through the pipe P2, so that heat exchange with the radiation shield 17 occurs only at the portion where the pipe P1 passes.

Thus, when it is unnecessary to increase the efficiency of heat exchange with the radiation shield 17 (e.g., during additional injection of refrigerant, excitation, or demagnetization), the efficiency of cooling the radiation shield 17 is not increased without an increase in the efficiency of heat exchange between the refrigerant gas and the radiation shield 17. This makes it possible to prevent the temperature of the radiation shield 17 from being excessively lowered relative to the steady state, due to injection of the refrigerant into the refrigerant container during additional injection of the refrigerant, excitation, demagnetization, or the like. As a result, the time to be taken to bring the temperature of the radiation shield 17 into the steady state (80 K in present exemplary embodiment) can be reduced.

### First Modification of First Exemplary Embodiment

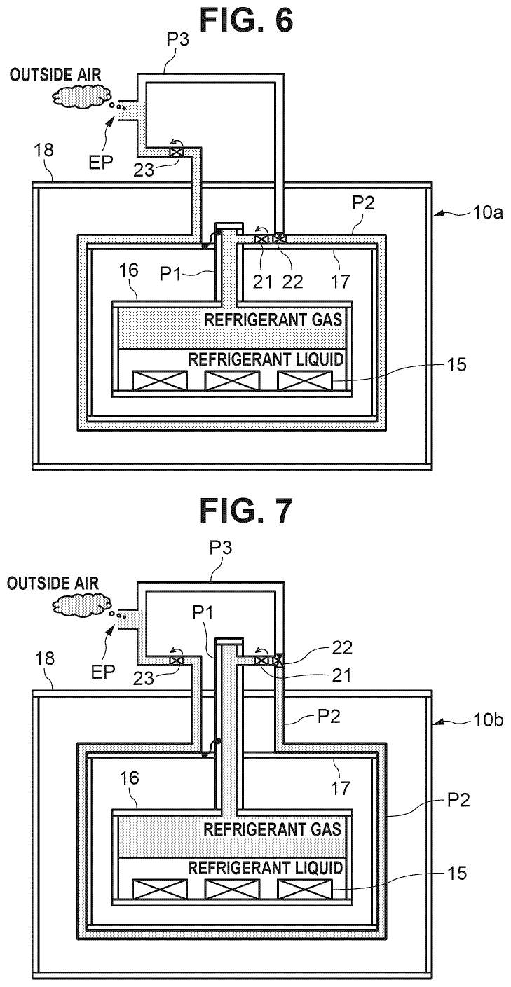

FIG. 6 is a sectional view illustrating a configuration of a static magnetic field magnet 10a and a periphery thereof according to a first modification of the first exemplary embodiment. In FIG. 2, the pipe P1 extends up to the outside of the vacuum container 18, and is connected to the pipes P2 and P3 on the outside of the static magnetic field magnet 10a. In other words, a branching point from the pipe P1 into the pipes P2 and P3 is disposed on the outside of the vacuum container 18. With this configuration, the refrigerant gas passing through the pipe P2 exchanges heat with the radiation shield 17 after being affected by the outside air once (e.g., temperature rises).

On the other hand, in FIG. 6, the pipe P1 is laid to penetrate outward through the radiation shield 17, and then immediately run along the outer surface of the radiation shield 17. The pipe P1 is then connected to the pipes P2 and P3. In other words, the branching point from the pipe P1 to the pipes P2 and P3 is disposed inside the vacuum container 18. The pipe P2 goes around the radiation shield 17 inside the vacuum container 18 (without going out of vacuum container 18). Thus, the refrigerant gas passing through the pipe P2 is not affected by the outside air, and can exchange heat with the radiation shield 17 in a low temperature state as compared with that in the configuration illustrated in FIG. 2.

### Second Modification of First Exemplary Embodiment

FIG. 7 is a sectional view illustrating a configuration of a static magnetic field magnet 10b and a periphery thereof according to a second modification of the first exemplary embodiment. It is desirable that the pipe P2 be made of a material that prevents the refrigerant gas from leaking into the static magnetic field magnet 10b. As illustrated n FIG. 7, out of the pipe P2, a part that externally contacts the radiation shield 17 may have high thermal conductivity, and a part that does not externally contact the radiation shield 17 may have low thermal conductivity.

For example, the part of the pipe P2 that externally contacts the radiation shield 17 may be replaced with a pipe made of copper or aluminum, which has high thermal conductivity. This makes it possible to increase the efficiency of heat exchange between the refrigerant gas passing through the pipe P2 and the radiation shield 17. On the other hand, the part of the pipe P2 that does not externally contact the radiation shield 17 may be replaced with a pipe made of stainless steel (steel use stainless [SUS]), which has low thermal conductivity. Thus, in a case where the pipe P2 is exposed to the outside air, heat intrusion from the outside air into the pipe P2 can be prevented.

The static magnetic field magnets 10, 10a, and 10b according to the first exemplary embodiment each include the pipe P2 that goes around the radiation shield 17 and discharges the refrigerant gas in the refrigerant container 16 to the outside, in addition to the pipe P3 that directly discharges the refrigerant gas in the refrigerant container 16 to the outside. This enables the refrigerant gas that is to be discharged for adjustment of the pressure inside the refrigerant container 16 to be effectively used for cooling the radiation shield 17. The efficiency of heat exchange between the refrigerant gas and the radiation shield 17 can be intentionally changed as necessary.

### Second Exemplary Embodiment

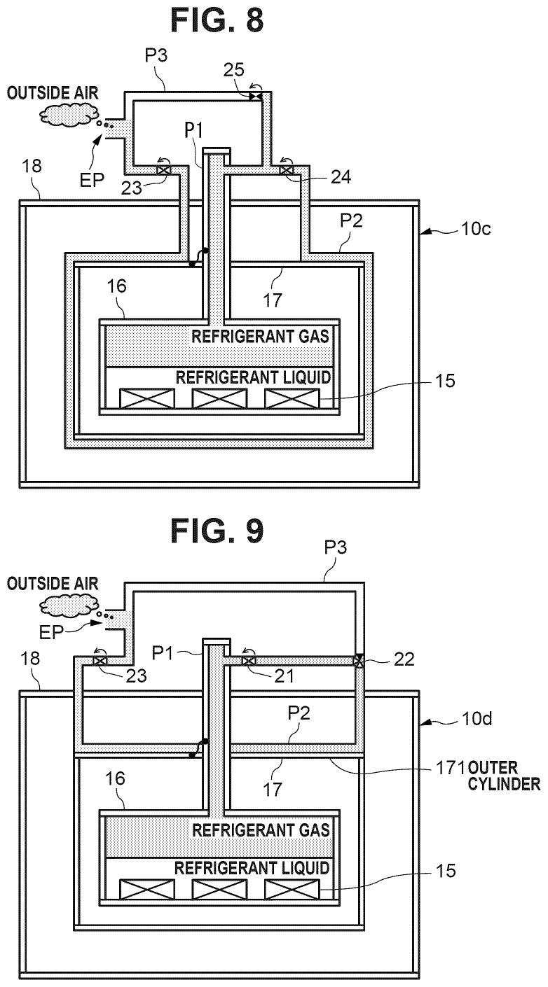

FIG. 8 is a sectional view illustrating a configuration of a static magnetic field magnet 10c and a periphery thereof according to a second exemplary embodiment. The first exemplary embodiment and the second exemplary embodiment are different in arrangement and operation of the valves. As illustrated in FIG. 8, valves 24 and 25 introduce the refrigerant gas introduced from the pipe P1, to the pipe P2 or the pipe P3 in conjunction with each other. The valves 23, 24, and 25 are examples of the switching assembly.

The valve 24 is installed in the pipe P2 near a portion that is connected to the pipe P1, and opens or closes based on pressure of the refrigerant gas introduced from the pipe P1. When the pressure of the refrigerant gas introduced from the pipe P1 exceeds a predetermined threshold, the valve 24 allows the refrigerant gas to pass into the inside of the pipe P2. The valve 24 prevents the refrigerant gas from reversely flowing from the pipe P2 into the pipe P1. For the valve 24, a check valve is used, for example. The valve 24 is an example of a first valve.

The valve 25 is disposed in the pipe P3 near a portion that is connected to the pipe P1, and opens or closes based on pressure of the refrigerant gas introduced from the pipe P1. When the pressure of the refrigerant gas introduced from the pipe P1 exceeds a predetermined threshold, the valve 25 allows the refrigerant gas to pass into the inside of the pipe P3. The valve 25 prevents the refrigerant gas from reversely flowing from the pipe P3 into the pipe P1. For the valve 25, a check valve is used, for example. The valve 25 is an example of a second valve.

The valve 23 is disposed in the pipe P2 between the static magnetic field magnet 10c (vacuum container 18) and the exhaust port EP, and opens or closes based on pressure of the refrigerant gas in the pipe P2. When the pressure of the refrigerant gas in the pipe P2 exceeds a predetermined threshold, the valve 23 allows the refrigerant gas to pass from the pipe P2 to the exhaust port EP side. The valve 23 prevents the refrigerant gas from reversely flowing from the exhaust port EP side of the pipe P2 into the pipe P2. For the valve 23, a check valve is used, for example. The valve 23 is an example of a third valve. The exhaust port EP of the pipe P2 is an example of a portion for discharging the refrigerant gas to the outside. The valve 24 opens the path when the pressure of the refrigerant gas exceeds a first threshold. The valve 25 opens the path when the pressure of the refrigerant gas exceeds a second threshold that is greater than the first threshold. For example, the first threshold for the valve 24 is set to 7000 [Pa], and the second threshold for the valve 25 is set to 20000 [Pa]. Thus, when the pressure of the refrigerant gas in the refrigerant container 16 exceeds 7000 [Pa], the refrigerant gas flows into the pipe P2 on the radiation shield 17 side. When the pressure of the refrigerant gas exceeds 20000 [Pa], the refrigerant gas also flows into the pipe P3 in addition to the pipe P2, and is directly discharged to the outside.

The valve 23 opens the path when the pressure of the refrigerant gas exceeds a third threshold greater than the first threshold. When the pressure of the refrigerant gas exceeds the first threshold, the refrigerant gas accumulates in the pipe P2. When the temperature of the refrigerant gas rises, and the pressure of the refrigerant gas exceeds the third threshold, the refrigerant gas is discharged to the outside air. In FIG. 8, the valves 23 and 24 open the paths, but the valve 25 closes the path. Thus, the refrigerant gas passes through the pipes P1 and P2, and is then discharged from the exhaust port EP to the outside air.

In the static magnetic field magnet 10c according to the second exemplary embodiment, in a case where operation pressure of the respective three valves 23, 24, and 25 can be determined, check valves may be used for the three valves. This eliminates the need for a switching valve thereby eliminating the manual switching operation for the refrigerant gas path. Subsequently, when the pressure in the refrigerant container 16 increases and the refrigerant gas is discharged to the outside air, the refrigerant gas is initially caused to pass through the pipe P2 and is discharged to the outside air while going around the radiation shield 17. When the pressure of the refrigerant gas further increases, the refrigerant gas is caused to pass through the pipe P3 and is directly discharged to the outside air. This enables the refrigerant gas that is to be discharged for adjustment of the pressure inside the refrigerant container 16 to be preferentially used for cooling the radiation shield 17. Since the refrigerant gas is temporarily accumulated in the pipe P2, it is possible to enhance the efficiency of heat exchange between the refrigerant gas and the radiation shield 17.

### Third Exemplary Embodiment

In the first exemplary embodiment and the second exemplary embodiment, the configuration in which the pipe P2 goes around the entire radiation shield 17 is described. In the third exemplary embodiment, the pipe P2 externally contacts a part (predetermined part) of the radiation shield 17.

FIG. 9 is a sectional view illustrating a configuration of a static magnetic field magnet 10d and a periphery thereof according to the third exemplary embodiment. As illustrated in FIG. 9, the pipe P2 externally contacts the outer cylinder 171 of the radiation shield 17. For example, during transportation of a product of the magnetic resonance imaging apparatus 1, a refrigeration machine provided in the radiation shield 17 does not operate. Thus, the outer cylinder 171 of the radiation shield 17 is likely to be warmed. The above-described configuration enables the outer cylinder 171 of the radiation shield 17 to be cooled in such a case.

FIG. 10 is a sectional view illustrating a configuration of a static magnetic field magnet 10e and a periphery thereof according to the third exemplary embodiment. As illustrated in FIG. 10, the pipe P2 externally contacts the end plates 172 of the radiation shield 17. For example, during transportation of a product of the magnetic resonance imaging apparatus 1, the refrigeration machine provided in the radiation shield 17 does not operate. Thus, the end plates 172 of the radiation shield 17 are likely to be warmed. The above-described configuration enables the end plates 172 of the radiation shield 17 to be cooled in such a case.

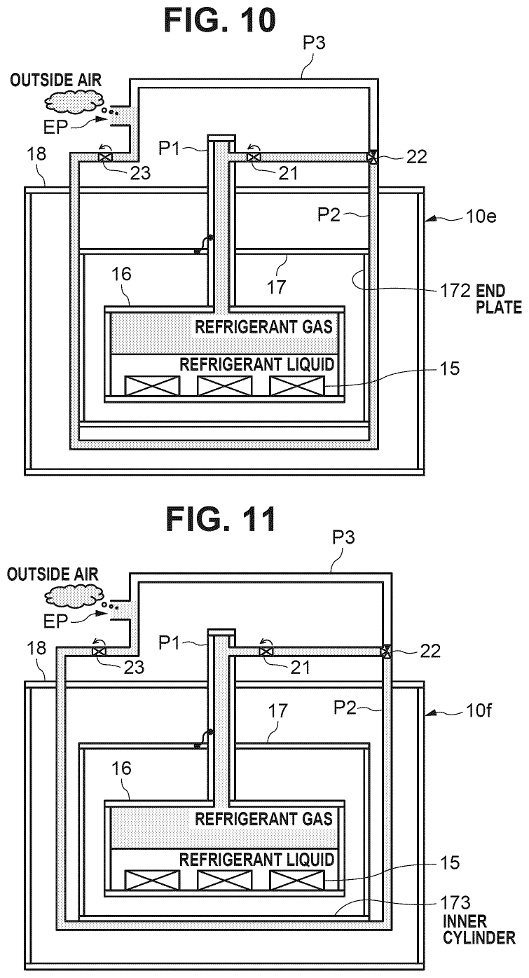

FIG. 11 is a sectional view illustrating a configuration of a static magnetic field magnet 10f and a periphery thereof according to the third exemplary embodiment. As illustrated in FIG. 11, the pipe P2 externally contacts the inner cylinder 173 of the radiation shield 17. For example, when the magnetic resonance imaging apparatus 1 is imaging the subject, the inner cylinder 173 close to the gradient magnetic field coil 11 is likely to be warmed as compared with the outer cylinder 171, due to eddy current loss of the radiation shield 17 caused by application of the gradient magnetic field. When a quench occurs, causing a sudden drop in the magnetic force generated by the static magnetic field magnet 10, the inner cylinder 173 which is close to the position where the superconducting coil 15 with a large number of windings is located is likely to be warmed due to eddy current loss, as compared with the outer cylinder 171 in the radiation shield 17. This configuration enables the inner cylinder 173 of the radiation shield 17 to be cooled in such a case.

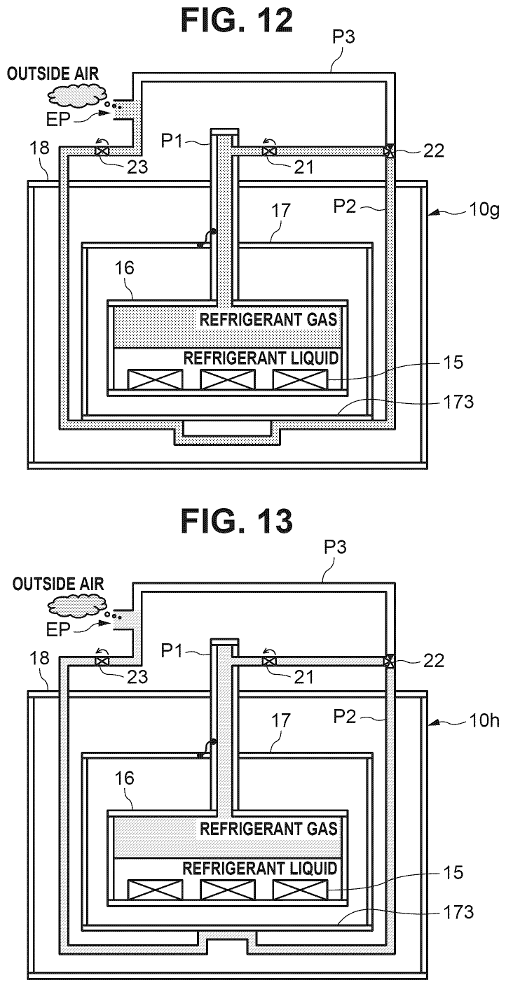

FIG. 12 is a sectional view illustrating a configuration of a static magnetic field magnet 10g and a periphery thereof according to the third exemplary embodiment. As illustrated in FIG. 12, the pipe P2 externally contacts both outer sides in a cylinder axis direction, of the inner cylinder 173 of the radiation shield 17. For example, both outer sides are likely to be warmed as compared with an inner part (center part) of the radiation shield 17 in the axis direction. This configuration enables both outer sides of the inner cylinder 173 of the radiation shield 17 to be cooled in such a case.

FIG. 13 is a sectional view illustrating a configuration of a static magnetic field magnet 10h and a periphery thereof according to the third exemplary embodiment. As illustrated in FIG. 13, the pipe P2 externally contacts an inner part (center part) in the cylinder axis direction, of the inner cylinder 173 of the radiation shield 17. For example, depending on the arrangement of the gradient magnetic field coil 11, the inner part of the radiation shield 17 in the axial direction may generate heat due to eddy current caused by the gradient magnetic field. This configuration enables the inner part of the inner cylinder 173 of the radiation shield 17 to be cooled in such a case.

According to the third exemplary embodiment, each of the static magnetic field magnets 10d to 10h at least includes the pipe P2 which causes the refrigerant gas capable of exchanging heat with the radiation shield 17, to flow through a predetermined part where the efficiency of heat exchange with the radiation shield 17 is to be increased, and the valve 22 that allows selection of the path through which the refrigerant gas flows. This makes it possible to increase the efficiency of heat exchange with the radiation shield 17, and to increase the efficiency of cooling the radiation shield 17.

### Fourth Exemplary Embodiment

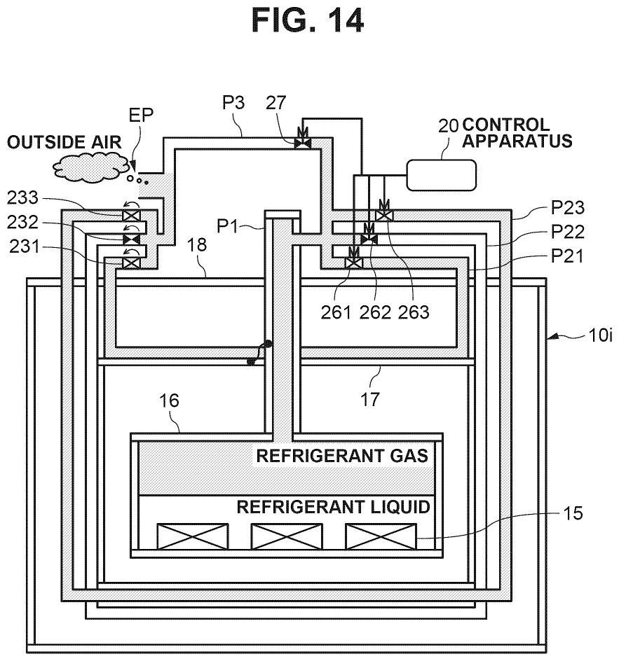

FIG. 14 is a diagram illustrating a configuration of a static magnetic field magnet 10i and a periphery thereof according to a fourth exemplary embodiment. As illustrated in FIG. 14, the static magnetic field magnet 10i according to the fourth exemplary embodiment further includes a control apparatus 20, as compared with the first to third exemplary embodiments.

In the fourth exemplary embodiment, in place of the pipe P2 according to the first to third exemplary embodiments, sub-pipes P21, P22, and P23 are branched from the pipe P1. In other words, the pipe P2 is branched into the sub-pipes P21, P22, and P23 on a downstream of the portion connected to the pipe P1. The sub-pipes P21, P22, and P23 each externally contact different parts of the radiation shield 17 to exchange heat with the radiation shield 17, merged after heat exchange, and connected to the exhaust port EP for discharging the refrigerant gas to the outside air. The sub-pipe P21 externally contacts the outer cylinder 171 of the radiation shield 17. The sub-pipe P22 externally contacts the end plates 172 of the radiation shield 17. The sub-pipe P23 externally contacts the inner cylinder 173 of the radiation shield 17. The sub-pipes P21, P22, and P23 are examples of a plurality of second sub-pipes.

Valves 261, 262, and 263 are installed at positions before positions at which the sub-pipes P21, P22, and P23 exchange heat with the radiation shield 17, respectively, and opens or closes in response to an instruction of the control apparatus 20. A valve 27 is installed in the pipe P3, and opens or closes in response to an instruction of the control apparatus 20. The valves 261, 262, 263, and 27 are each configured to adjust a flow rate of the refrigerant gas. The flow rate of the refrigerant gas can be adjusted, for example, based on an opening degree of each of the valves. The valves 261, 262, 263, and 27 may be any valves that can be controlled to open and close by the control apparatus 20, such as electric valves or solenoid valves. The valves 261, 262, and 263 are examples of a plurality of first valves. The valve 27 is an example of a second valve.

The control apparatus 20 selects the valves to open from among the valves 261, 262, 263, and 27, and instructs the selected valve to open the path. The control apparatus 20 adjusts the flow rate of the refrigerant gas in each of the valves 261, 262, 263, and 27.

Valves 231, 232, and 233 are disposed at positions near a portion where the sub-pipes P21, P22, and P23 are merged, and opens or closes based on the pressure of the refrigerant gas in the sub-pipes P21, P22, and P23. The valves 231, 232, and 233 allow the refrigerant gas to pass from inside to outside of the sub-pipes P21, P22, and P23, respectively, when the pressure of the refrigerant gas in the corresponding one of the sub-pipes P21, P22, and P23 exceeds a predetermined threshold. Each of the valves 231, 232, and 233 prevents the refrigerant gas from reversely flowing from the outside into the inside of the corresponding one of the sub-pipes P21, P22, and P23. For the valves 231, 232, and 233, check valves are used, for example. Even with the operating pressure of the valves 231, 232, and 233 set equal to one another, if pressure losses of the sub-pipes P21, P22, and P23 are different from one another, the refrigerant gas may largely flow through the pipe with the small pressure loss even though the valves 261, 262, and 263 are fully opened. Therefore, it is desirable that the pressure losses of the sub-pipes P21, P22, and P23 be set equal to one another as much as possible. This makes it possible to adjust the flow rate of the refrigerant gas. Shapes, lengths, and cross-sectional areas of the sub-pipes P21, P22, and P23 may be changed. This makes it possible to adjust the pressure loss of the flow of the refrigerant gas. For example, to minimize the pressure loss, a cross-section of each of the sub-pipes P21, P22, and P23 is generally formed in a circular shape.

According to the fourth exemplary embodiment, the static magnetic field magnet 10i includes the sub-pipes P21, P22, and

P23 that allow the refrigerant gas capable of exchanging heat with the radiation shield 17, to pass through a predetermined part where the efficiency of heat exchange with the radiation shield 17 is to be increased, the valves that can switch the path through which the refrigerant gas flows, the part of the radiation shield 17, and the flow rate, and the control apparatus 20. This makes it possible to increase the efficiency of heat exchange between the refrigerant gas and the radiation shield 17, and to increase the efficiency of cooling the radiation shield 17.

According to the above-described at least one exemplary embodiment, the efficiency of heat exchange between the refrigerant of the superconducting coils and the radiation shield can be changed in the magnetic resonance imaging apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus, comprising:
a superconducting coil;
a first container that houses the superconducting coil and in which the superconducting coil is immersed in refrigerant liquid and refrigerant gas generated by vaporization of the refrigerant liquid is contained;
a radiation shield housing the first container;
a second container housing the radiation shield;
a first pipe configured to direct the refrigerant gas in the first container, to an outside of the radiation shield;
a second pipe connected to the first pipe, and configured to allow the refrigerant gas from the first pipe, to pass therethrough so as to enable the refrigerant gas to exchange heat with the radiation shield;
a third pipe connected to the first pipe, and configured to discharge the refrigerant gas from the first pipe, to an outside; and
a switching assembly configured to direct the refrigerant gas from the first pipe, to the second pipe or the third pipe.

2. The magnetic resonance imaging apparatus according to claim 1,
wherein the second pipe allows the refrigerant gas from the first pipe, to pass through so as to enable the refrigerant gas to exchange heat with the radiation shield, and then discharges the refrigerant gas to the outside, and
wherein the switching assembly includes:
a first valve disposed in the second pipe near a portion connected to the first pipe and configured to open or close based on pressure of the refrigerant gas from the first pipe;
a second valve disposed in the third pipe near a portion connected to the first pipe and configured to open or close based on the pressure of the refrigerant gas from the first pipe; and
a third valve disposed in the second pipe between the second container and a portion for discharging the refrigerant gas to the outside and configured to open or close based on the pressure of the refrigerant gas.

3. The magnetic resonance imaging apparatus according to claim 2,
wherein the first valve opens when the pressure of the refrigerant gas exceeds a first threshold, and
wherein the second valve opens when the pressure of the refrigerant gas exceeds a second threshold greater than the first threshold.

4. The magnetic resonance imaging apparats according to claim 2,
wherein the first valve opens when the pressure of the refrigerant gas exceeds a first threshold, and
wherein the third valve opens when the pressure of the refrigerant gas exceeds a third threshold greater than the first threshold.

5. The magnetic resonance imaging apparatus according to claim 1, wherein the second pipe externally contacts a predetermined part of the radiation shield.

6. The magnetic resonance imaging apparatus according to claim 5, wherein the predetermined part is an outer cylinder, an end plate, an inner cylinder, or a part of the inner cylinder of the radiation shield.

7. The magnetic resonance imaging apparatus according to claim 1, wherein, in the second pipe, a part that externally contacts the radiation shield has high thermal conductivity, and a part that does not externally contact the radiation shield has low thermal conductivity.

8. The magnetic resonance imaging apparatus according to claim 1, further comprising a control apparatus,
wherein the second pipe is branched into a plurality of second sub-pipes on a downstream of a portion connected to the first pipe,
wherein the plurality of second sub-pipes is configured such that the plurality of second sub-pipes each externally contacts different parts of the radiation shield to exchange heat with the radiation shield and discharges the refrigerant gas to the outside after heat exchange,
wherein the switching assembly includes:
a plurality of first valves each disposed at positions before positions at which the plurality of second sub-pipes exchanges heat with the radiation shield and configured to open or close in response to an instruction of the control apparatus; and
a second valve disposed in the third pipe and configured to open or close in response to an instruction of the control apparatus, and
wherein the control apparatus selects a valve to open from among the plurality of first valves and the second valve, and instructs the selected valve to open.

9. The magnetic resonance imaging apparatus according to claim 8,
wherein the plurality of first valves and the second valve are configured such that a flow rate of the refrigerant gas is adjustable, and
wherein the control apparatus adjusts the flow rate of the refrigerant gas in the plurality of first valves and the second valve.
